(19) United States
(12) Patent Application Publication
(10) Pub. No.: US 2009/0096949 A1
(43) Pub. Date: Apr. 16, 2009

(54) THIN FILM TRANSISTOR ARRAY PANEL, METHOD FOR MANUFACTURING THE SAME AND DISPLAY DEVICE WITH THE SAME

(75) Inventors: Seung-hwan CHO, Hwaseong-si (KR); Bo-sung KIM, Seoul (KR); Keun- Kyu SONG, Yongin-si (KR); Jung-hun NOH, Yongin-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 12/187,687

(22) Filed: Aug. 7, 2008

(30) Foreign Application Priority Data
Oct. 12, 2007 (KR) 10-2007-0103207

(51) Int. Cl. G02F 1/136; H01L 51/05; H01L 51/40

(52) U.S. Cl. 349/43; 257/40; 438/99; 257/E51.006

(57) ABSTRACT

A thin film transistor array panel includes an insulating substrate, a first conductive layer disposed on the insulating substrate, an organic semiconductor disposed between the source electrode and the drain electrode, a gate insulating layer disposed on the organic semiconductor, and a second conductive layer disposed on the gate insulating layer. The first conductive layer includes a data line, a source electrode connected to the data line, a drain electrode spaced apart from the source electrode, and a pixel electrode connected to the drain electrode and formed of the same layer as the drain electrode, and the second conductive layer includes a gate line and a gate electrode connected to the gate line.

### CROSS-REFERENCE TO RELATED APPLICATIONS

This application claims priority from and the benefit of Korean Patent Application No. 10-2007-0103207, filed on Oct. 12, 2007, which is hereby incorporated by reference for all purposes as if fully set forth herein.

### BACKGROUND OF INVENTION

1. Field of the Invention

The present invention relates to a thin film transistor array panel having an organic semiconductor, a method for manufacturing the same, and a display device with the same.

2. Discussion of the Background

A flat panel display apparatus, such as a liquid crystal display (LCD), an organic light emitting device (OLED), or an electrophoretic display, includes a plurality of electrodes and an electro-optical activation layer activated by the electrodes. The electro-optical activation layer is a liquid crystal layer in an LCD, an organic light emitting layer in an OLED, and a charged particle layer in an electrophoretic display.

The plurality of electrodes includes a pixel electrode connected to a switching element to apply an electric signal to the electro-optical activation layer and a common electrode as a reference electrode. The electro-optical activation layer converts an electric signal from the pixel electrode into an optical signal to display an image.

A flat panel display generally uses a thin film transistor (TFT) as a switching element. To control the TFT, the flat panel display may include a gate line to transmit a scan signal and a data line to transmit a data voltage to be applied to the pixel electrode.

Among TFTs, an organic TFT (OTFT) including an organic semiconductor has been more actively studied than an inorganic semiconductor including silicon (Si). The OTFTs are arranged in a matrix array on an insulating substrate to form an OTFT array panel.

The OTFT array panel may include a variety of wires and insulating layers.

### SUMMARY OF INVENTION

Additional features of the invention will be set forth in the description which follows, and in part will be apparent from the description, or may be learned by practice of the invention.

The present invention discloses a thin film transistor array panel including an insulating substrate, a first conductive layer disposed on the insulating substrate, the first conductive layer including a data line, a source electrode connected to the data line, a drain electrode spaced apart from the source electrode, and a pixel electrode connected to the drain electrode and formed of the same layer as the drain electrode, an organic semiconductor disposed between the source electrode and the drain electrode, a gate insulating layer disposed on the organic semiconductor, and a second conductive layer disposed on the gate insulating layer. The second conductive layer includes a gate line and a gate electrode connected to the gate line.

The present invention also discloses a method for manufacturing a thin film transistor array panel including sequentially forming a first layer including a transparent conductive material and a second layer including a metallic material on an insulating substrate to form a first conductive layer, the first conductive layer including a data line, a source electrode connected to the data line, a drain electrode spaced apart from the source electrode, and a pixel electrode connected to the drain electrode, forming an organic semiconductor on the source electrode and the drain electrode, forming an insulating material layer and a metal layer sequentially on the organic semiconductor, the source electrode, and the drain electrode, forming an insulating layer member on the metal layer, and etching the metal layer and the insulating material layer to form a second conductive layer and a gate insulating layer, the second conductive layer including a gate line and a gate electrode.

The present invention also discloses a display apparatus including a first display panel including a first insulating substrate, a second display panel including a second insulating substrate disposed opposite to the first insulating substrate, and a liquid crystal layer disposed between the first display panel and the second display panel. The first display panel includes a first conductive layer disposed on the first insulating substrate and including a data line, a source electrode connected to the data line, a drain electrode spaced apart from the source electrode, and a pixel electrode connected to the drain electrode and formed of the same layer as the drain electrode, an organic semiconductor disposed between the source electrode and the drain electrode, a gate insulating layer disposed on the organic semiconductor, and a second conductive layer disposed on the gate insulating layer and including a gate line and a gate electrode connected to the gate line.

The present invention also discloses a display apparatus including a first display panel including a first insulating substrate, a second display panel including a second insulating substrate and disposed opposite to the first insulating substrate, and a charged particle layer disposed between the first display panel and the second display panel and including a charged particle. The first display panel includes a first conductive layer disposed on the first insulating substrate and including a data line, a source electrode connected to the data line, a drain electrode spaced from the source electrode, and a pixel electrode connected to the drain electrode and formed of the same layer as the drain electrode. An organic semiconductor is formed between the source electrode and the drain electrode, a gate insulating layer is formed on the organic semiconductor, and a second conductive layer is formed on the gate insulating layer and includes a gate line and a gate electrode connected to the gate line.

It is to be understood that both the foregoing general description and the following detailed description are exemplary and explanatory and are intended to provide further explanation of the invention as claimed.

### BRIEF DESCRIPTION OF DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is an arrangement view of a TFT array panel according to a first exemplary embodiment of the present invention.

FIG. 2 is a cross-sectional view of the TFT array panel taken along line II-II in FIG. 1.

FIG. 3, FIG. 4, FIG. 5, FIG. 6, FIG. 7, FIG. 8B, FIG. 9, FIG. 10, FIG. 11, FIG. 12, FIG. 13, FIG. 14, and FIG. 15 are cross-sectional views sequentially showing a process of manufacturing the TFT array panel of FIG. 2.

FIG. 8A is an arrangement view of the TFT array panel of FIG. 8B.

FIG. 16 is a cross-sectional view of a TFT array panel having a passivation layer disposed on an organic layer according to a second exemplary embodiment of the present invention.

FIG. 17 is a cross-sectional view of a TFT array panel having a passivation layer disposed after removing an organic layer according to a third exemplary embodiment of the present invention.

FIG. 18 is a cross-sectional view of an LCD having the TFT array panel according to the first exemplary embodiment of the present invention.

FIG. 19 is a cross-sectional view of another LCD having the TFT array panel according to the first exemplary embodiment of the present invention.

FIG. 20 is a cross-sectional view of an electrophoretic display having the TFT array panel according to the first exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

In the following exemplary embodiments, display devices with an LCD or an electrophoretic display will be described, but the present invention is not limited thereto. Other display devices, such as an OLED, are also within the scope of the present invention.

### First Exemplary Embodiment

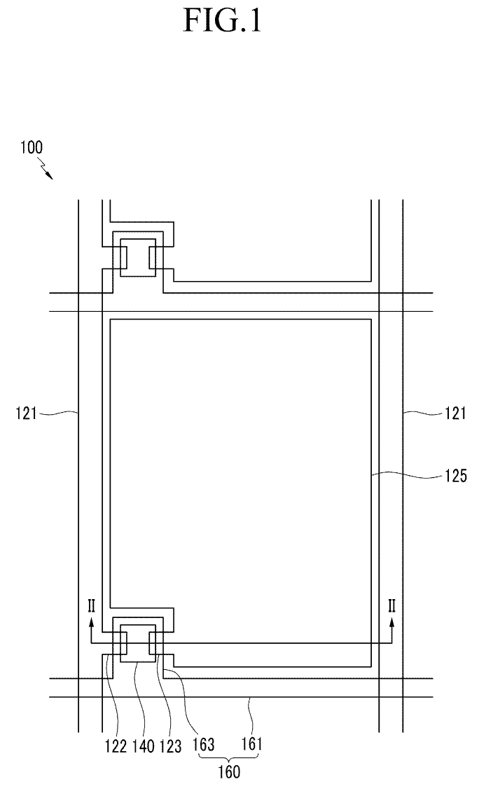

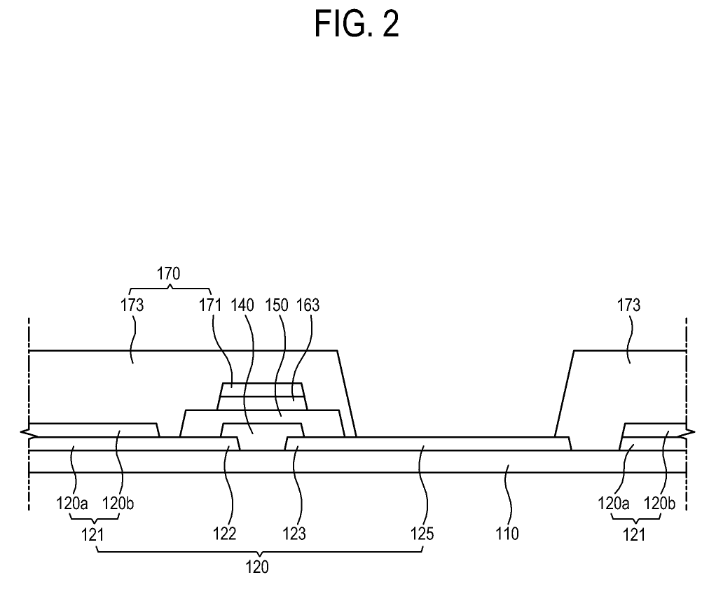

FIG. 1 and FIG. 2 are an arrangement view and a cross-sectional view of a TFT array panel according to a first exemplary embodiment of the present invention. As shown in the drawings, a TFT array panel 100 includes an insulating substrate 110, a first conductive layer 120 disposed on the insulating substrate 110, organic semiconductors 140 contacting source electrodes 122 and drain electrodes 123 of the first conductive layer 120, a gate insulating layer 150 disposed on the organic semiconductors 140, a second conductive layer 160 disposed on the gate insulating layer 150, and an insulating layer 170 disposed on the second conductive layer 160.

The insulating substrate 110 may be made of transparent glass, silicon, plastic, or the like. The first conductive layer 120, which includes data lines 121, the source electrodes 122, and the drain electrodes 123, is disposed on the insulating substrate 110.

In the present exemplary embodiment, the first conductive layer 120 is disposed directly on the insulating substrate 110 to directly contact the insulating substrate 110. Alternatively, an additional layer may be disposed between the insulating substrate 110 and the first conductive layer 120.

The data lines 121 transmit data signals and extend longitudinally, as shown in FIG. 1. Each data line 121 includes a data pad (not shown) to be connected with a driving circuit provided on a different layer or outside of the display area. The data lines 121 may be a double layer including a first layer 120a and a second layer 120b on the first layer 120a.

The first layer 120a is disposed directly on the insulating substrate 110. The first layer 120a is formed of the same layer as the source electrode 122, the drain electrode 123, and a pixel electrode 125. The first layer 120a may include a transparent conductive material. For example, the first layer 120a may include indium tin oxide (ITO) or indium zinc oxide (IZO).

The second layer 120b is disposed directly on the first layer 120a and is not disposed on the source electrode 122, the drain electrode 123, and the pixel electrode 125. The second layer 120b may include metal. For example, the second layer 120b may include a low resistive metal such as molybdenum (Mo), molybdenum alloys, chrome (Cr), chrome alloys, aluminum (Al), aluminum alloys, copper (Cu), copper alloys, silver (Ag), silver alloys, and the like. Here, the second layer 120b may include a material with a different etching selectivity than the first layer 120a.

The source electrodes 122 protrude from the data line 121 laterally. The source electrodes 122 are formed of the same layer as the first layers 120a. For example, the source electrodes 122 may be made of a transparent conductive material, such as ITO or IZO.

The drain electrodes 123 are spaced apart from the source electrodes 122 and arranged opposite to the source electrodes 122. The drain electrodes 123 are formed of the same layer as the first layers 120a, as well as the source electrodes 122.

The pixel electrodes 125 are connected to the drain electrodes 123 and formed of the same layer as the first layer 120a, as well as the source electrodes 122 and the drain electrodes 123. For example, the pixel electrodes 125 may be made of a transparent conductive material, such as ITO or IZO.

Each of the pixel electrodes 125 receives a data voltage from TFTs to generate an electric field along with a common electrode (not shown) that receives a common voltage. Accordingly, an electro-optical activation layer, such as a liquid crystal layer, disposed between the two electrodes converts an electric signal into an optical signal, thereby displaying an image.

The organic semiconductors 140 are disposed on the insulating substrate 110 between the source electrodes 122 and the drain electrodes 123 and contacts the source electrodes 122 and the drain electrodes 123. The organic semiconductors 140 may include a polymer or a low molecular weight compound soluble in water or an organic solvent. In the present exemplary embodiment, the organic semiconductors 140 may be formed by an ink-jet printing method including jetting a solution and evaporating water or organic solvent.

The organic semiconductors 140 may include a derivative having a substituent of tetracene or a substituent of pentacene. The organic semiconductors 140 may also include oligothiophene having 4, 5, 6, 7, or 8 thiopenes connected to the 2^{nd} and 5^{th} positions of a thiophene ring.

Further, the organic semiconductors 140 may include polythienylenevinylene, poly 3-hexylthiophene, polythiophene, phthalocyanine, metallized phthalocyanine, or halogenated derivatives thereof. The organic semiconductor layers 140 may also include perylenetetracarboxylic dianhydride (PTCDA), naphthalenetetracarboxylic dianhydride (NTCDA), or image derivatives thereof. Lastly, the semiconductor layers 140 may include perylene, coronene, or a derivative including a substituent of perylene or coronene.

The organic semiconductors 140 may have a thickness of about 300 Å to about 1 μm.

The TFT array panel 100 according to the first exemplary embodiment includes organic semiconductors 140 disposed between the source electrodes 122 and the drain electrodes 123 without banks serving as an additional insulating layer. In this case, the organic semiconductors 140 may be formed by adjusting a contact angle of jetted organic semiconductor solution by surface treating the source electrodes 122, the drain electrodes 123, and the insulating substrate 110. For example, the source electrodes 122, the drain electrodes 123, and the insulating substrate 110 may become similar in surface tension through surface treatment so that the organic semiconductor solution may be prevented from traveling away from the insulating substrate 110 to the source electrodes 122 and the drain electrodes 123. Alternatively, there may be banks exposing portions of the source electrodes 122 and portions of the drain electrodes 123, and the organic semiconductors 140 may be disposed on the exposed portions.

The gate insulating layer 150 is disposed on the organic semiconductors 140. The gate insulating layer 150 may be disposed on portions of the source electrodes 122 and portions of the drain electrodes 123 where the organic semiconductors 140 is not disposed so as to substantially cover the organic semiconductors 140. The gate insulating layer 150 may be disposed on the data lines 121 as well. That is, the gate insulating layer 150 may be disposed on the source electrodes 122, the drain electrodes 123, and the data lines 121 to provide insulation and protection when an additional passivation layer 173 is not disposed thereon.

The gate insulating layer 150 may be made of polyacryl, a derivative of polyacryl, polystyrene, a derivative of polystyrene, benzocyclobutane (BCB), polyimde, a derivative of polyimide, polyvinyl alcohol, a derivative of polyvinyl alcohol, parylene, a derivative of parylene, perfluorocyclobutane, a derivative of perfluorocyclobutane, perfluorovinylether, or a derivative of perfluorovinylether.

The second conductive layer 160 is disposed directly on the gate insulating layer 150. The second conductive layer 160 may include gate lines 161 and gate electrodes 163 connected to the gate lines 161. The second conductive layer 160 may be made of a low resistive metal such as molybdenum (Mo), molybdenum alloys, chrome (Cr), chrome alloys, aluminum (Al), aluminum alloys, copper (Cu), copper alloys, silver (Ag), silver alloys, or the like.

The gate lines 161 transmit gate signals and substantially extend in a transverse direction on FIG. 1 to cross the data lines 121. Each of the gate lines 161 includes a gate pad (not shown) to be connected with a driving circuit (not shown) provided on a different layer or outside of the display area.

The gate electrodes 163 overlap with the organic semiconductors 140, and the gate insulating layer 150 is positioned therebetween. The gate electrodes 163 protrude from the gate line 161 upward. A parasitic capacities (Cgs) are formed between the gate electrodes 163 and the source electrodes 122 and between the gate electrodes 163 and the drain electrodes 123. To minimize the parasitic capacities, the areas where the source electrodes 122 overlap with the gate electrodes 163, and areas where the drain electrodes 123 overlap with the gate electrodes 163 should be minimized. Thus, the gate electrodes 163 disposed on the gate insulating layer 150 are narrower than the gate insulating layer 150 and correspond to the organic semiconductors 140.

The insulating layer 170 is disposed on the second conductive layer 160. In the present exemplary embodiment, the insulating layer 170 includes organic layers 171 disposed on and corresponding to the gate electrodes 163. Further, the insulating layer 170 may further include a passivation layer 173 disposed on the organic layers 171.

In the present exemplary embodiment, the organic layers 171 are disposed on the gate electrodes 163 and the gate lines 161. That is, when the passivation layer 173 is omitted, the organic layers 171 may be disposed on the gate electrodes 163 and the gate lines 161 to protect the gate electrodes 163 and the gate lines 161. The organic layers 171 may be disposed to correspond to the gate lines 161. The organic layers 171 may include an acrylic organic material.

The passivation layer 173 protects the TFT and the second conductive layer 160. However, the passivation layer 173 may be disposed on a partial or whole surface of the insulating substrate 110 or be omitted as necessary (refer to the second exemplary embodiment described below).

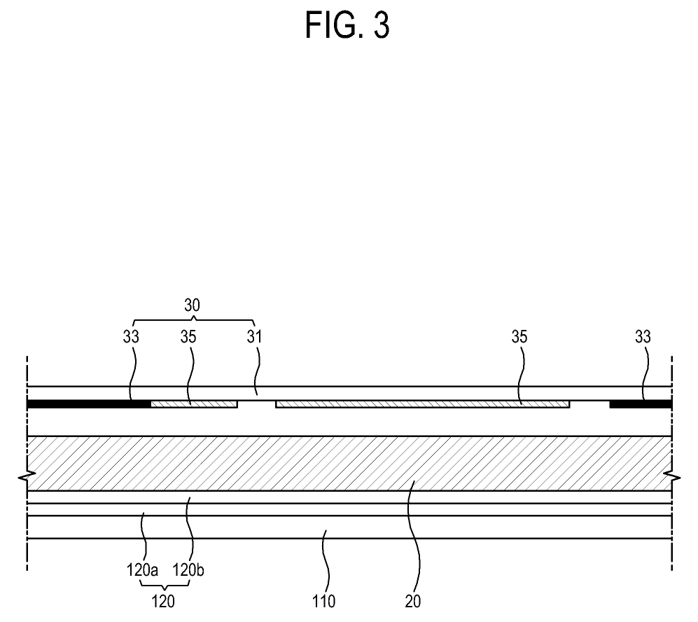

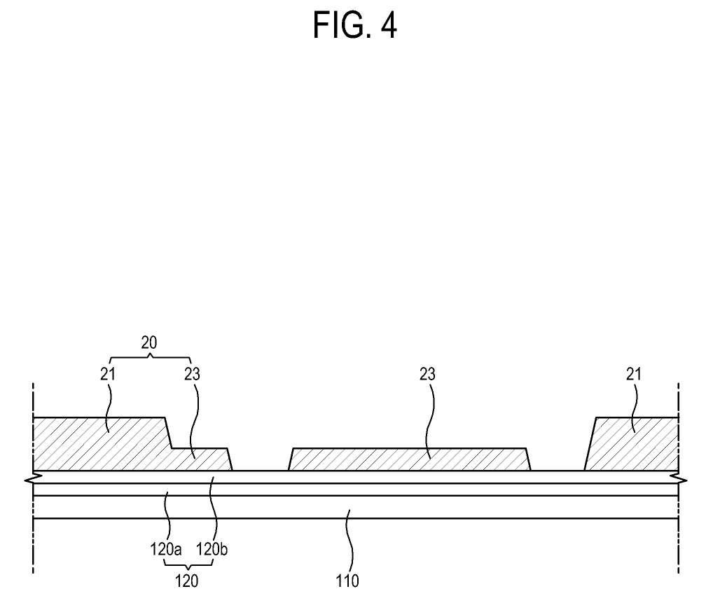

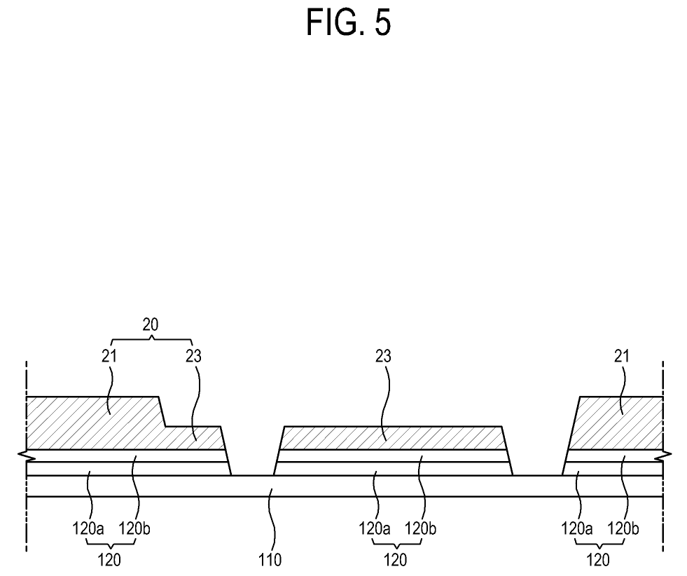

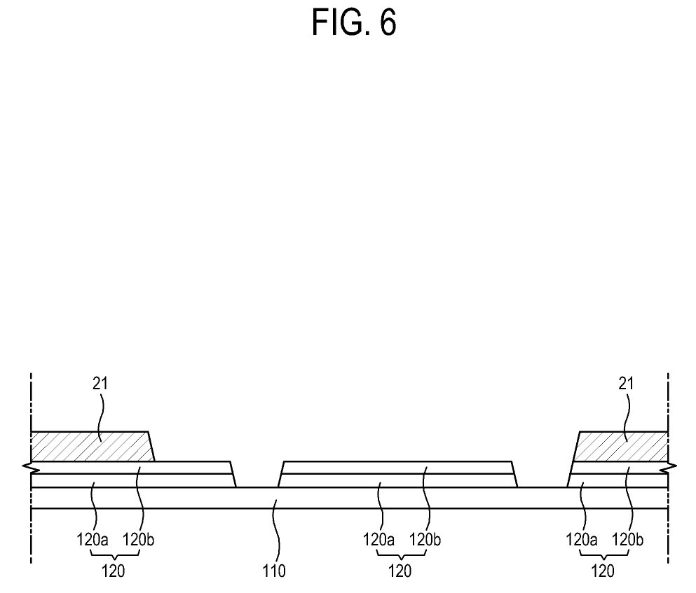

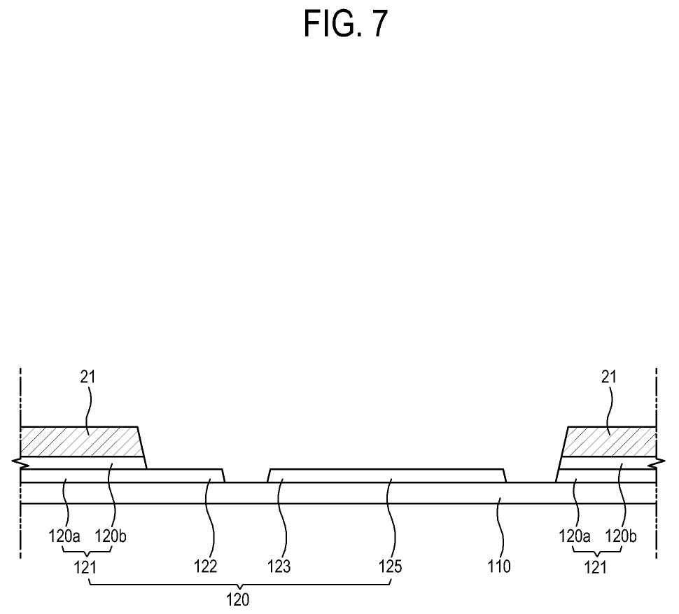

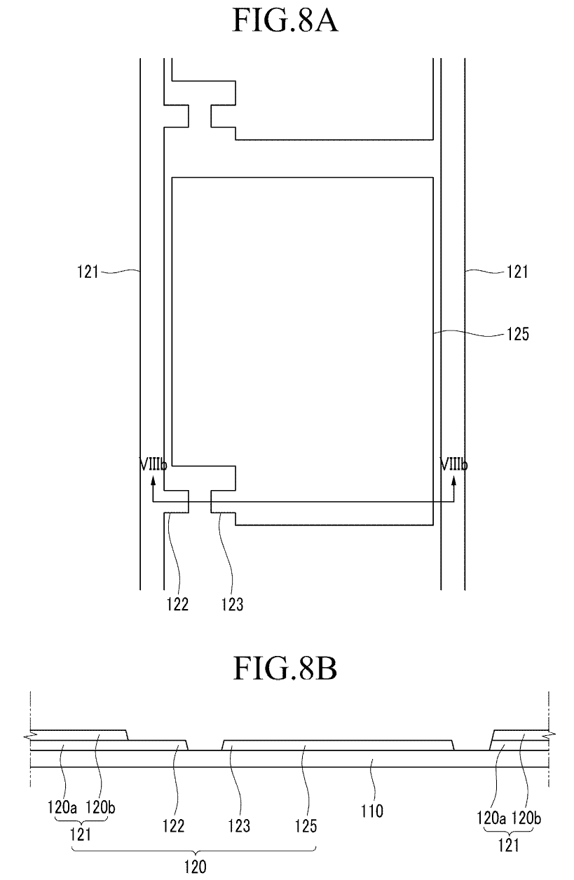

FIG. 3, FIG. 4, FIG. 5, FIG. 6, FIG. 7, FIG. 8A, FIG. 8B, FIG. 9, FIG. 10, FIG. 11, FIG. 12, FIG. 13, and FIG. 14 show a method for manufacturing the TFT array panel according to the first exemplary embodiment of the present invention. Referring to the drawings, the method for manufacturing the TFT array panel 100 according to the first exemplary embodiment of the present invention will be described in detail.

FIG. 3 is a cross-sectional view showing a process where a first layer 120a and a second layer 120b are sequentially deposited on the insulating substrate 110, a photoresist member 20 is applied, and a mask 30 is arranged. In the present exemplary embodiment, the first layer 120a may include ITO, and the second layer 120b may include molybdenum. Exposing is carried out using the mask 30 disposed above the photoresist member 20.

The mask 30 may include a mask substrate 31 made of a transparent material, a light blocking part 33 to block light, and a semi-transmitting part 35 to semi-transmit light. The mask substrate 31 may be made of a transparent material, such as quartz or the like. The light blocking part 33 may include chrome (Cr) or the like and may be disposed on the mask substrate 31 to block light. The semi-transmitting part 35 may include chrome (Cr) or the like and may be formed in a slit pattern on the mask substrate 31. However, the semi-transmitting part 35 may be formed in a lattice pattern and may have about half of the transmittance and about half of the thickness as the light blocking part 33. In the case of the slit pattern, the width of the slit or an interval between slits may be smaller than the resolution of an exposer.

As shown in FIG. 4, after the photoresist member 20 is exposed and developed using the mask 30, the photoresist member 20 may include a first photoresist member 21 and a second photoresist member 23 that have different thicknesses. The second photoresist member 23 may be thinner than the first photoresist member 21. The thickness ratio of the first photoresist member 21 to the second photoresist member 23 may vary depending on conditions during etching. In the present exemplary embodiment, the second photoresist member 23 may have half or less of the thickness of the first photoresist member 21.

Referring to FIG. 5, unnecessary portions of the second layer 120b are etched using the first photoresist member 21 and the second photoresist member 23 as a mask. Here, the etching of the second layer 120b may be wet-etching using an etching solution for molybdenum that does not etch the first layer 120a, which includes ITO with a different etching selectivity.

Subsequently, unnecessary portions of the first layer 120a are etched using the first photoresist member 21 and the second photoresist member 23 as a mask, thereby completing the first layer 120a of the first conductive layer 120. Here, the etching of the first layer 120a may be wet-etching using an etching solution for ITO. However, the first and second layers 120a and 120b may be etched simultaneously by dry-etching using the first photoresist member 21 and the second photoresist member 23 as a mask.

Referring to FIG. 6, the second photoresist member 23 is removed through an etch back process such as ashing. Here, the first photoresist member 21 may decrease in thickness.

Referring to FIG. 7, exposed portions of the second layer 120b are etched using the thinner first photoresist member 21 as a mask. Here, the etching of the second layer 120b is carried out with an etching solution for molybdenum, and thus the first layer 120a, which includes of ITO with a different etching selectivity, is not etched. Accordingly, source electrodes 122, drain electrodes 123, and pixel electrodes 125 in the first layer 120a are formed.

Referring to FIGS. 8A and 8B, the first photoresist member 21 disposed on the data lines 121 is removed. Accordingly, the data lines 121, including the first layer 120a and the second layer 120b, are disposed on the insulating substrate 110, and the source electrodes 122, the drain electrodes 123, and the pixel electrodes 125 are formed in the first layer 120a.

As described above, the TFT array panel 100 according to the first exemplary embodiment of the present invention includes the data lines 121, the source electrodes 122, the drain electrodes 123, and the pixel electrodes 125 that are all formed using a single mask, which may simplify the manufacturing process.

Referring to FIG. 9, organic semiconductors 140 are disposed between the source electrodes 122 and the drain electrodes 123 and contact the source electrodes 122 and the drain electrodes 123. The organic semiconductors 140 may be formed by jetting an organic semiconductor solution through an ink-jet printing method and evaporating the solvent in the solution. In the present exemplary embodiment, without using banks, the organic semiconductor solution is jetted onto the insulating substrate 110 between the source electrodes 122 and the drain electrodes 123, onto the source electrodes 122, and onto the drain electrodes 123, thereby forming the organic semiconductors 140. A proper surface treatment may be needed to form the organic semiconductors 140 without banks, which was described above.

Accordingly, the TFT array panel according to the first exemplary embodiment of the present invention may include the organic semiconductors 140 without using bank so that the mask is used fewer times, which may simplify the manufacturing process.

Referring to FIG. 10, an insulating material layer 50 and a metal layer 60 are sequentially deposited on the entire surface of the insulating substrate 110. The insulating material layer 50, for example, may include a fluoropolymer.

Referring to FIG. 11, an insulating layer member 70 is coated on the metal layer 60 and exposed using a mask 80. Here, the mask 80 includes a mask substrate 81, a light blocking part 83 to block light, and a semi-transmitting part 85, just like the mask 30 shown in FIG. 3. The mask 80 is similar to the mask 30 in FIG. 3, which is omitted from the description.

Using the mask 80, as shown in FIG. 12, the insulating layer member 70 is formed to include a first insulating layer member 71 and a second insulating layer member 73 that have different thicknesses. The first and second insulating layer members 71 and 73 are similar to the first and second photoresist members 21 and 23, which are not repeatedly described.

Referring to FIG. 13, the metal layer 60 and the insulating material layer 50 are etched with the first and second insulating layer members 71 and 73 as a mask. Accordingly, gate insulating layer 150 is formed. Here, the etching of the insulating material layer 50 may be carried out with wet-etching using an etching solution for a suitable insulating material, by which the first layer 120a including ITO and the second layer 120b including molybdenum with a different etching selectivity are not etched.

Referring to FIG. 14, the second insulating layer member 73 is removed through an etch back process such as ashing. Here, the first insulating layer member 71 decreases in thickness.

Referring to FIG. 15, exposed portions of the metal layer 60 are etched using the first insulating layer member 71 as a mask. Accordingly, second conductive layer 160 including gate electrodes 163 and gate lines 161 is formed. The first insulating layer member 71 remains and functions as organic layers 171. The organic layers 171 are disposed on and corresponding to the gate electrodes 163. Further, the organic layers 171 may be disposed to correspond to the gate lines 161.

As described above, in the TFT array panel 100 according to the first exemplary embodiment of the present invention, the gate insulating layer 150, the gate lines 161, and the gate electrodes 163 are formed using a single mask, which may simplify the manufacturing process.

Then, as shown in FIG. 2, an organic material is deposited on the entire surface of the insulating substrate 110, exposed, and developed, thereby forming a passivation layer 173 exposing the pixel electrodes 125. The passivation layer 173 protects the TFT and the second conductive layer 160. However, the passivation layer 173 may be omitted as necessary (refer to the second exemplary embodiment described below). Further, the passivation layer 173 may be formed after removing the organic layers 171, which is the first insulating layer member 71 that was used as a mask when forming the second conductive layer 160 (refer to the third exemplary embodiment described below).

Thus, as for the method for manufacturing the TFT array panel 100 according to the first exemplary embodiment of the present invention, the data lines 121, the source electrodes 122, the drain electrodes 123, and the pixel electrodes 125 are formed using a single mask, the organic semiconductors 140 is formed without using banks, and the gate insulating layer 150, the gate lines 161, and the gate electrodes 163 are formed using a single mask so that the manufacturing process may be simplified.

### Second Exemplary Embodiment

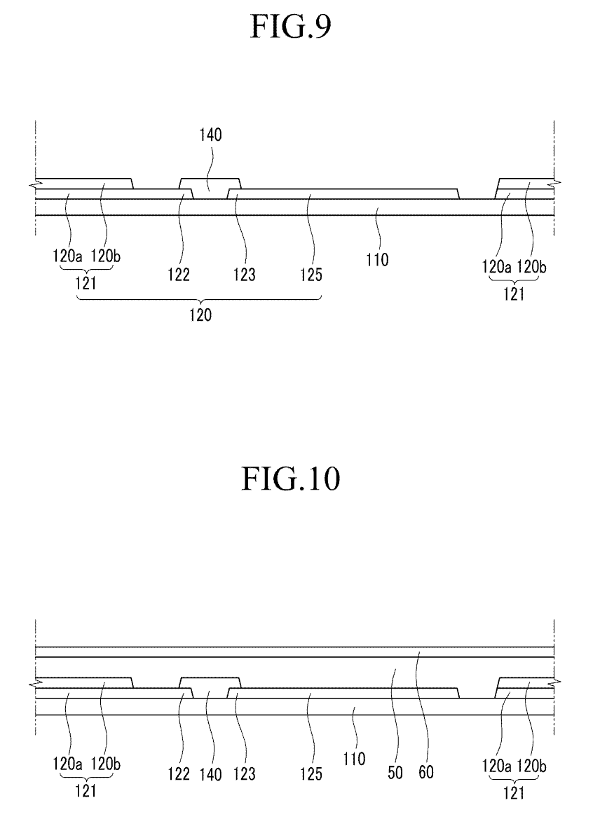

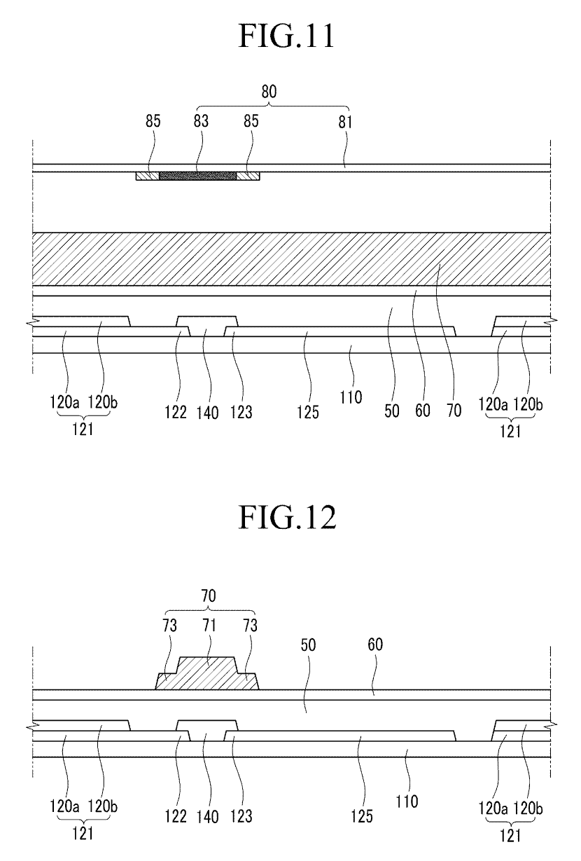

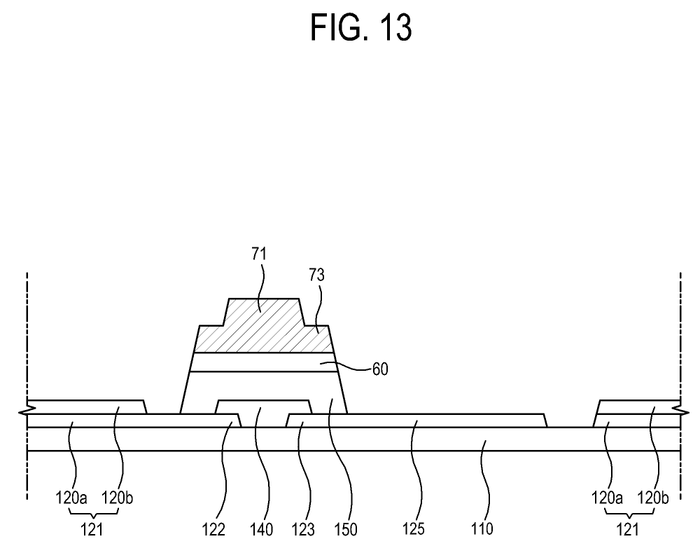

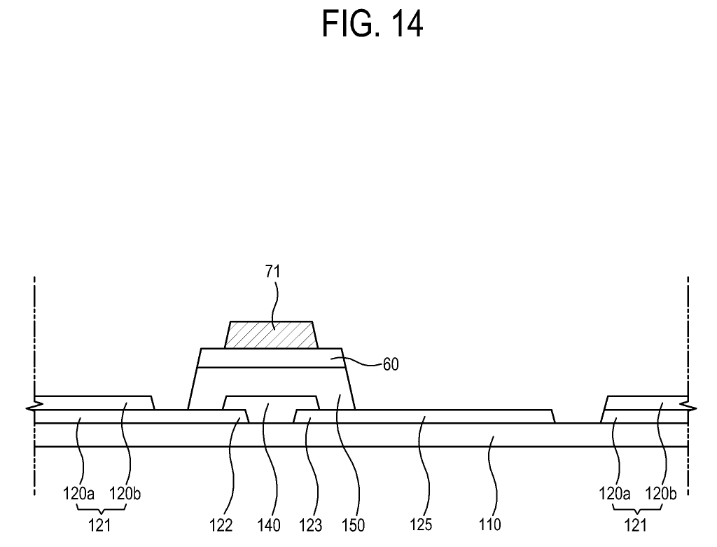

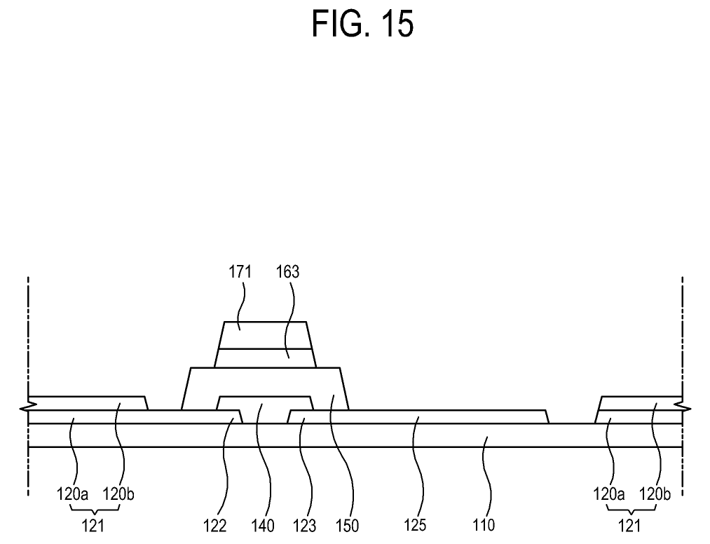

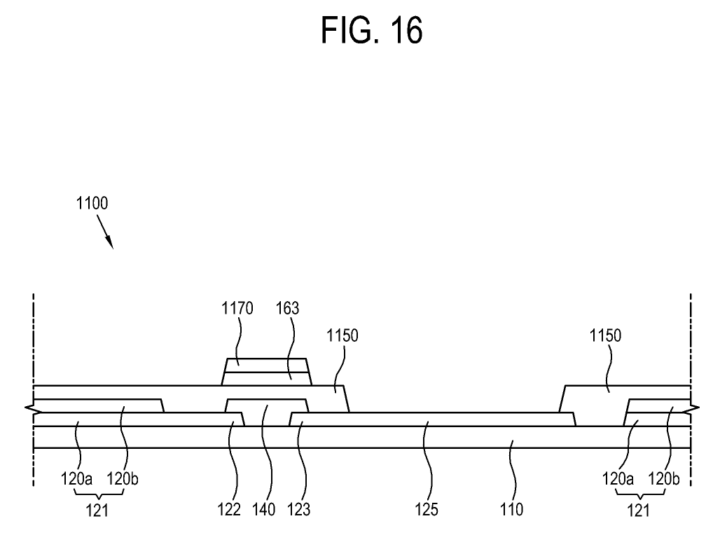

FIG. 16 is a cross-sectional view of a TFT array panel according to a second exemplary embodiment of the present invention.

As shown, insulating layers 1170 of a TFT array panel 1100 according to a second exemplary embodiment do not have the passivation layers 173 disposed on the organic layers 171 as in the first exemplary embodiment. That is, the insulating layers 1170 in the second exemplary embodiment are similar to the organic layers 171 excluding the passivation layer 173 in the first exemplary embodiment.

The insulating layers 1170 are disposed on a gate electrodes 163 and gate line 161s, and a gate insulating layer 1150 is disposed on data lines 121, source electrodes 122, and drain electrodes 123. Accordingly, a passivation layer may not be necessary to further protect the gate lines 161 or the TFTs.

Thus, in the TFT array panel 1100 according to the second exemplary embodiment of the present invention, the passivation layer is omitted, thereby the manufacturing process may be even more simplified than with the first exemplary embodiment.

### Third Exemplary Embodiment

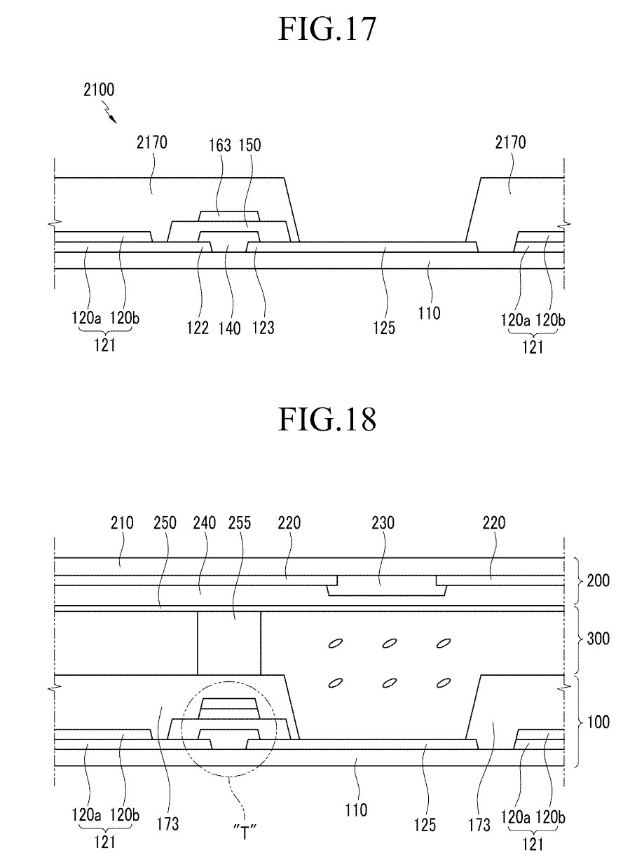

FIG. 17 is a cross-sectional view of a TFT array panel according to a third exemplary embodiment of the present invention.

As shown, an insulating layer 2170 of a TFT array panel 2100 according to a third exemplary embodiment is formed with a passivation layer 173 after removing the organic layers 171. That is, the insulating layer 2170 in the third exemplary embodiment is similar to the passivation layer 173 excluding the organic layers 171 in the first exemplary embodiment.

The insulating layer 2170 is arranged to expose pixel electrodes 125 by depositing an organic material on the entire surface of an insulating substrate 110, exposing, and developing.

FIG. 18 is a cross-sectional view of an LCD equipped with the TFT array panel according to the first exemplary embodiment of the present invention. The display device, the LCD, includes a first display panel 100 having a first insulating substrate 110, a second display panel 200 having a second insulating substrate 210 disposed opposite to the first insulating substrate 110, and a liquid crystal layer 300 disposed between the first display panel 100 and the second display panel 200.

The first display panel 100 is the same as the aforementioned TFT array panel 100, which is not repeatedly described, only noting that the insulating substrate 110 of the TFT array panel 100 is defined as the first insulating substrate 110 of the first display panel 100. Namely, with reference to FIG. 18, the first conductive layer 120 is disposed on the first insulating substrate 110.

Hereinafter, the second display panel 200 is described in detail.

A black matrix 220 is disposed on the second insulating substrate 210. The black matrix 220 is disposed between red, green, and blue color filters to divide the color filters and prevents light from being irradiated directly from the TFTs (T) on the first display panel 100. The black matrix 220 may be made of a photoresist organic material including a black pigment. The black pigment may be carbon black or the like. Further, the black matrix 220 may include metal, such as chrome oxide or the like.

A color filters 230 are disposed on the second insulating substrate 210 at a position corresponding to each pixel electrode 125. The color filters 230 includes red, green, and blue filters that are alternately disposed and spaced apart by the black matrix 220. The color filters 230 colors light irradiated from a backlight unit (not shown) and passing through the liquid crystal layer 300. The color filters 230 may be made of a photoresist organic material. The color filters 230 may be arranged only on the first display panel 100 or may be omitted according to a driving type of the backlight unit.

An overcoat layer 240 is disposed on the color filters 230 and the portions of the black matrix 220 that are not covered with the color filters 230. The overcoat layer 240 provides a planar surface and protects the color filters 230. The overcoat layer 240 may be made of an acrylic epoxy material.

A common electrode 250 is disposed on the overcoat layer 240. The common electrode 250 may be made of a transparent conductive material, such as ITO or IZO. The common electrode 250 applies a voltage to the liquid crystal layer 300 along with the pixel electrodes 125 of the first display panel 100. Cell gap spacers 255 are disposed on the common electrode 250, and the TFTs (T) are disposed on the first display panel 100 below the cell gap spacers 255. The cell gap spacers 255 serve to maintain a regular distance between the first display panel 100 and the second display panel 200. Liquid crystals are injected into the space between the two display panels 100 and 200, which are spaced apart by the cell gap spacers 255.

The liquid crystal layer 300 having liquid crystal molecules is disposed between the first display panel 100 and the second display panel 200.

Thus, in the display device having the TFT array panel according to the first exemplary embodiment of the present invention, the data lines 121, the source electrodes 122, the drain electrodes 123, and the pixel electrodes 125 are formed using a single mask, the organic semiconductors 140 are formed without using banks, and the gate insulating layer 150, the gate lines 161, and the gate electrodes 163 are formed using a single mask so that the manufacturing process may be simplified.

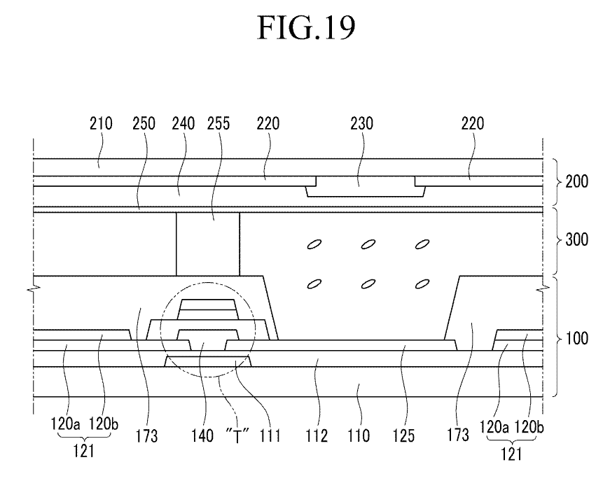

FIG. 19 is a cross-sectional view of another LCD equipped with the TFT array panel according to the first exemplary embodiment of the present invention.

The description of a display device is made focusing on differences from FIG. 18 with reference to FIG. 19. The display device further includes light blocking layers 111 provided to prevent light generated in a light source (not shown), such as a backlight unit, from entering an organic semiconductors 140 of a TFT array panel 100 and an insulating layer 112 disposed between the light blocking layers 111 and a first conductive layer 120.

The light blocking layers 111 are disposed on an insulating substrate 110 corresponding to the areas of the organic semiconductors 140 to prevent light from the light source from reaching the organic semiconductors 140. When light from the light source enters the organic semiconductors 140, the properties of the organic semiconductors 140 may be deteriorated.

In the present exemplary embodiment, the light blocking layers 111 may include the same metal as a second layer 120b of a first conductive layer 120. In this case, it is required to prepare an insulating layer 112 between the light blocking layers 111 and the first conductive layer 120. However, the light blocking layers 111 is not limited thereto but may include the same material as the aforementioned black matrix 220. In this case, the insulating layer 112 between the light blocking layers 111 and the first conductive layer 120 may be omitted.

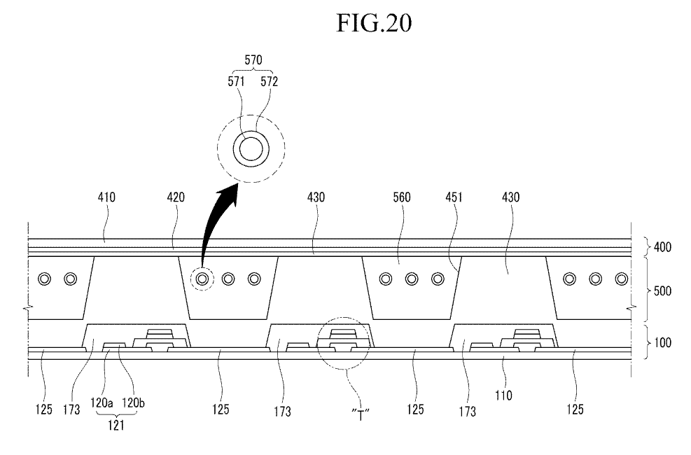

FIG. 20 is a cross-sectional view of an electrophoretic display device equipped with the TFT array panel according to the first exemplary embodiment of the present invention. An electrophoretic display device includes a first display panel 100 having a first insulating substrate 110, a second display panel 400 having a second insulating substrate 410 disposed opposite to the first insulating substrate 110, and a charged particle layer 500 disposed between the first and second display panels 100 and 400 and having a fluid 560 and charged particles 570 injected in the fluid 560. The charged particles 571 include positive charged particles and negative charged particles.

The first display panel 100 is substantially the same as the aforementioned TFT array panel 100, which will not described in detail, only noting that the insulating substrate 110 of the TFT array panel 100 is defined as the first insulating substrate 110 of the first display panel 100. Namely, with reference to FIG. 20, a first conductive layer 120 is disposed on the first insulating substrate 110.

The second display panel 400 is described in the following.

A common electrode 420 and a sealing/adhering layer 430 are disposed on the second insulating substrate 410.

The common electrode 420 may be made of a transparent conductive material, such as ITO or IZO. The common electrode 420 is arranged on the entire surface of the second insulating substrate 410 and forms an electric field along with pixel electrodes 125 to drive the positive or negative charged particles 570.

The sealing/adhering layer 430 is adhered to walls 450 to prevent the charged particles 570 in one pixel from transferring to another pixel. The sealing/adhering layer 430 may include a polymer. Alternatively, the sealing/adhering layer 430 may be prepared independently from the second display panel 400 and adhered to the second display panel 400 during an assembly process.

In the electrophoretic display device according to the present exemplary embodiment, neither the first display panel 100 nor the second display panel 200 includes color filters. The electrophoretic display device achieves colors through the color represented by movement of the charged particles 570 in the pixels.

The walls 450 are disposed between the first display panel 100 and the second display panel 400. The walls 450 separate the pixels and prevent the charged particles 570 in one pixel from transferring to another pixel.

The walls 450 form accommodating parts 451 to accommodate the fluid 560.

In the present exemplary embodiment, the accommodating parts 451 of the walls 450 may have a micro-cup shape. However, it is not limited thereto and may be formed in a micro-capsule shape having a spherical shape.

The fluid 560 accommodated in the accommodating parts 451 of the walls 450 may have low viscosity to allow for high mobility of the charged particles 570 and a low dielectric constant to inhibit a chemical reaction. Further, the fluid 560 may be transparent to secure reflected brightness. The fluid 560, for example, may include a hydrocarbon, such as decahydronaphthalene, 5-ethylidene-2-norbornene, fatty oil, paraffin oil, or the like, an aromatic hydrocarbon, such as toluene, xylene, phenylxylylethane, dodecylbenzene, alkyl naphthalene, or the like, or halogenated solvents, such as perfluorodecaline, perfluorotoluene, perfluoroxylene, dichlorobenzotrifluoride, 3,4,5-trichlorobenzotrifluoride, chloropentafluoro-benzene, dichlorononane, pentachlorobenzene, or the like.

The charged particles 570 dispersed in the fluid 560 determine the color of each pixel. Each charged particle 570 includes a core 571 and a coloring layer 572 encompassing the core 571. The core 571 emits white light and may be made of titanium oxide (TiO₂) or silica (SiO₂). The coloring layer 572 colors the light one of red, blue, and green.

The charged particles 570 adjust the amount of reflected light while moving up and down according to an electric field formed between the pixel electrodes 125 and the common electrode 420. For example, when all charged particles 570 in one pixel are positioned adjacent to the second display panel 400, light reflected in pixels exhibiting red, green, and blue are mixed to give white. On the contrary, when all charged particles 570 are positioned adjacent to the first display panel 100, the amount of reflected light is decreased to emit black.

Each charged particle 570 may exhibit its own charge, be demonstratively charged using a charge control agent, or obtain a charge by floating on a solvent. The charge control agent may be a polymer or a non-polymer, ionic or non-ionic and, for example, may include sodium dodecylbenzene sulfonate, metal soap, polybutene succinimide, maleic anhydride copolymers, vinylpyridine copolymers, vinylpyrrolidone copolymer, (metha)acrylic acid copolymers, or the like.

The particles, such as the charged particles 570, the charge control agent, or the like, dispersed in the fluid 560 are required to satisfy the colloidal stability between each other, which is achieved by adjusting the size and surface charge of the particles.

Thus, in the electrophoretic display device having the TFT array panel 100 according to the first exemplary embodiment of the present invention, the data lines 121, the source electrodes 122, the drain electrodes 123, and the pixel electrodes 125 are formed using a single mask, the organic semiconductors 140 is formed without using banks, and the gate insulating layer 150, the gate lines 161, and the gate electrodes 163 are formed using a single mask so that the manufacturing process may be simplified.

In the foregoing descriptions with reference to FIG. 18, FIG. 19, and FIG. 20, the LCD or electrophoretic display device are equipped with the TFT array panel according to the first exemplary embodiment of the present invention, but the display devices may employ the TFT array panel according to the second or third exemplary embodiment.

Further, the TFT array panel according to exemplary embodiments of the present invention is mounted in the LCD or electrophoretic display device, but it may be mounted in other flat panel displays such as an organic light emitting device.

As described above, exemplary embodiments of the present invention provide a TFT array panel that may have a simplified manufacturing process.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A thin film transistor array panel comprising:
an insulating substrate:
a first conductive layer disposed on the insulating substrate, the first conductive layer comprising a data line, a source electrode connected to the data line, a drain electrode spaced apart from the source electrode, and a pixel electrode connected to the drain electrode and formed of the same layer as the drain electrode;
an organic semiconductor disposed between the source electrode and the drain electrode;
a gate insulating layer disposed on the organic semiconductor; and
a second conductive layer disposed on the gate insulating layer, the second conductive layer comprising a gate line and a gate electrode connected to the gate line.

2. The thin film transistor array panel of claim 1, wherein the data line comprises a first layer comprising a transparent conductive material and a second layer comprising a metallic material.

3. The thin film transistor array panel of claim 1, wherein the source electrode, the drain electrode, and the pixel electrode comprise a transparent conductive material.

4. The thin film transistor array panel of claim 2, wherein the transparent conductive material comprises at least one of indium tin oxide (ITO) and indium zinc oxide (IZO).

5. The thin film transistor array panel of claim 1, further comprising an organic layer disposed on the second conductive layer.

6. The thin film transistor array panel of claim 5, further comprising a passivation layer disposed on the organic layer.

7. The thin film transistor array panel of claim 1, further comprising a passivation layer disposed on the second conductive layer.

8. The thin film transistor array panel of claim 5, wherein the organic layer is disposed on the gate line.

9. A method for manufacturing a thin film transistor array panel comprising:
forming a first layer comprising a transparent conductive material and a second layer including a metallic material sequentially on an insulating substrate to form a first conductive layer, the first conductive layer comprising a data line, a source electrode connected to the data line, a drain electrode spaced apart from the source electrode, and a pixel electrode connected to the drain electrode;
forming an organic semiconductor on the source electrode and the drain electrode;
forming an insulating material layer and a metal layer sequentially on the organic semiconductor, the source electrode, and the drain electrode;
forming an insulating layer member on the metal layer; and
etching the metal layer and the insulating material layer to form a second conductive layer and a gate insulating layer, the second conductive layer comprising a gate line and a gate electrode.

10. The method of claim 9, wherein the formation of the first conductive layer comprises:
forming a photoresist member on the second layer;
exposing and developing the photoresist member to form a first photoresist member and a second photoresist member, the second photoresist member being thinner than the first photoresist member;
sequentially etching the second layer and the first layer using the first photoresist member and the second photoresist member as a first mask;
removing the second photoresist member; and
etching the second layer using the first photoresist member as a second mask.

11. The method of claim 10, wherein the second photoresist member is arranged where the source electrode, the drain electrode, and the pixel electrode are to be formed.

12. The method of claim 9, wherein the formation of the organic semiconductor comprises ink-jet printing.

13. The method of claim 9, wherein the formation of the second conductive layer and the gate insulating layer comprises:
exposing and developing the insulating layer member to form a first insulating layer member and a second insulating layer member thinner than the first insulating layer member;
etching the metal layer and the insulating material layer using the first insulating layer member and the second insulating layer member as a mask to form the gate insulating layer;
removing the second insulating layer member; and
etching the metal layer using the first insulating layer member as a second mask to form the second conductive layer.

14. The method of claim 13, further comprising forming a passivation layer on the first insulating layer member.

15. The method of claim 13, further comprising:
removing the first insulating layer member after forming the second conductive layer; and
forming a passivation layer on the second conductive layer and the gate insulating layer.

16. A display device comprising:
a first display panel comprising a first insulating substrate;
a second display panel comprising a second insulating substrate and disposed opposite to the first insulating substrate; and
a liquid crystal layer between the first display panel and the second display panel,
wherein the first display panel comprises a first conductive layer disposed on the first insulating substrate and comprising a data line, a source electrode connected to the data line, a drain electrode spaced apart from the source electrode, a pixel electrode connected to the drain electrode and formed of the same layer as the drain electrode, an organic semiconductor disposed between the source electrode and the drain electrode, a gate insulating layer disposed on the organic semiconductor, and a second conductive layer disposed on the gate insulating layer and comprising a gate line and a gate electrode connected to the gate line.

17. The display device of claim 16, wherein the data line comprises a first layer comprising a transparent conductive material and a second layer comprising a metallic material.

18. The display device of claim 16, wherein the source electrode, the drain electrode, and the pixel electrode comprise a transparent conductive material.

19. A display device comprising:
a first display panel comprising a first insulating substrate;
a second display panel comprising a second insulating substrate and disposed opposite to the first insulating substrate; and
a charged particle layer formed between the first display panel and the second display panel and comprising a charged particle,
wherein the first display panel comprises a first conductive layer disposed on the first insulating substrate and comprising a data line, a source electrode connected to the data line, a drain electrode spaced apart from the source electrode, a pixel electrode connected to the drain electrode and formed of the same layer as the drain electrode, an organic semiconductor disposed between the source electrode and the drain electrode, a gate insulating layer disposed on the organic semiconductor, and a second conductive layer disposed on the gate insulating layer and comprising a gate line and a gate electrode connected to the gate line.

20. The display device of claim 19, wherein the data line comprises a first layer comprising a transparent conductive material and a second layer comprising a metallic material.

21. The display device of claim 19, wherein the source electrode, the drain electrode, and the pixel electrode comprise a transparent conductive material.
